(19) United States
(12) Patent Application Publication
(10) Pub. No.: US 2009/0268386 A1
(43) Pub. Date: Oct. 29, 2009

(54) COMPUTER DEVICE CAPABLE OF CONTAINING AN EXTERNAL MODULE

(76) Inventor: Shih-Jeh Lin, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/176,408

(22) Filed: Jul. 20, 2008

(30) Foreign Application Priority Data
Apr. 23, 2008 (TW) 097114809

(51) Int. Cl. H05K 5/00; H05K 7/00

(52) U.S. Cl. 361/679.02

(57) ABSTRACT

A computer device includes a housing. An opening is formed on the housing and a containing space is formed inside the housing. The computer device further includes a first magnetic module exposing out of the opening partly and installed inside the housing in a movable manner, and a second magnetic module connected to an external module. When the first magnetic module moves to a first position, a first pole of the first magnetic module is located corresponding to a second pole of the second magnetic module so that the first magnetic module attracts the second magnetic module. When the first magnetic module moves to a second position, a second pole of the first magnetic module is located corresponding to the second pole of the second magnetic module so that the first magnetic module repulses the second magnetic module.

### BACKGROUND OF THE INVENTION

1. Field of the Invention

The present invention relates to a computer device capable of containing an external module, and more particularly, to a computer device capable of containing an external module with magnetic force.

2. Description of the Prior Art

A notebook computer has a characteristic of carrying conveniently. However, a user still has to carry input devices, such as a mouse, additionally so as to reduce convenience of carrying. Furthermore, it is inconvenient to accommodate a cable of the mouse. For solving this problem, Taiwan patent publication no. M281228 discloses a notebook computer whereon a slot is formed for accommodating a mouse with multiple functions. However aesthetic feeling of the notebook computer reduces due to the slot as a sunken part especially when the mouse is taken out, the mouse can not be fixed inside the slot tightly, and the mouse has to be received or disassembled by hand resulting in reducing convenience of usage.

### SUMMARY OF THE INVENTION

According to the claimed invention, a computer device includes a housing. An opening is formed on the housing and a containing space is formed inside the housing. The computer device further includes a first magnetic module exposing out of the opening partly and installed inside the housing in a movable manner, and a second magnetic module connected to an external module. When the first magnetic module moves to a first position, a first pole of the first magnetic module is located corresponding to a second pole of the second magnetic module so that the first magnetic module attracts the second magnetic module for containing the external module inside the containing space, and when the first magnetic module moves to a second position, a second pole of the first magnetic module is located corresponding to the second pole of the second magnetic module so that the first magnetic module repulses the second magnetic module for ejecting the external module out of the containing space.

According to the claimed invention, a computer system includes an external module, and a computer device including a housing. An opening is formed on the housing and a containing space is formed inside the housing. The computer system further includes a first magnetic module exposing out of the opening partly and installed inside the housing in a movable manner, and a second magnetic module connected to the external module. When the first magnetic module moves to a first position, a first pole of the first magnetic module is located corresponding to a second pole of the second magnetic module so that the first magnetic module attracts the second magnetic module for containing the external module inside the containing space, and when the first magnetic module moves to a second position, a second pole of the first magnetic module is located corresponding to the second pole of the second magnetic module so that the first magnetic module repulses the second magnetic module for ejecting the external module out of the containing space.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG.1 is a diagram of a computer system according to a preferred embodiment of the present invention.

FIG.2 is an enlarged diagram of an external module according to the preferred embodiment of the present invention.

FIG.3 is a diagram of a first magnetic module located in a first position according to the preferred embodiment of the present invention.

FIG.4 is a diagram of the first magnetic module located in a second position according to the preferred embodiment of the present invention.

FIG.5 is a diagram of the external module contained inside a containing space according to the preferred embodiment of the present invention.

### DETAILED DESCRIPTION

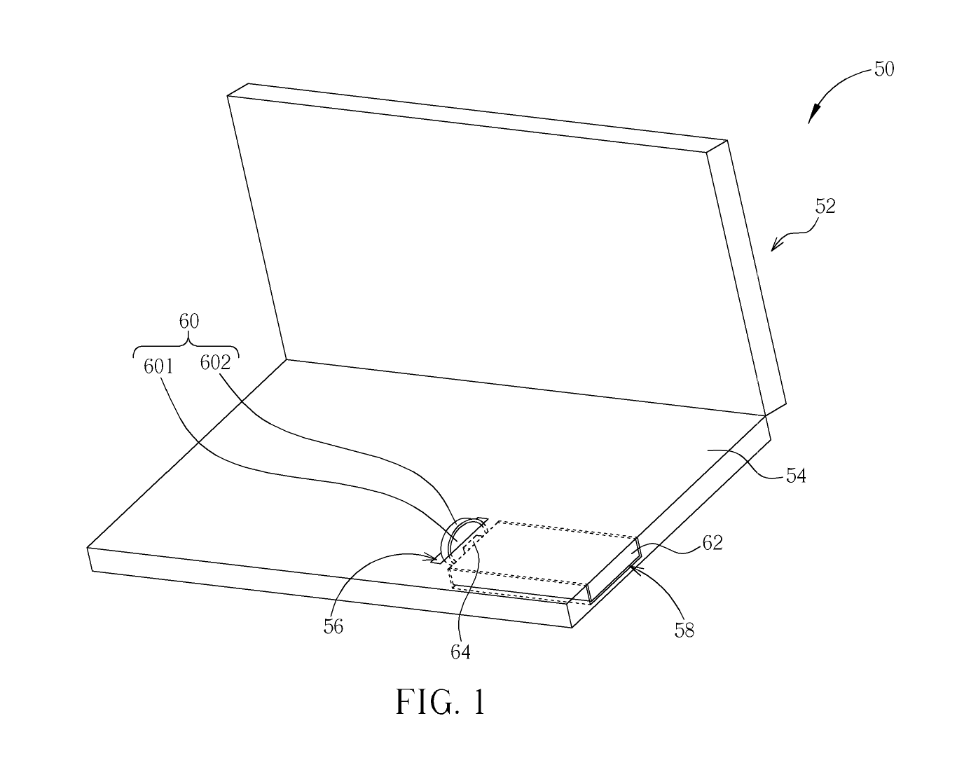

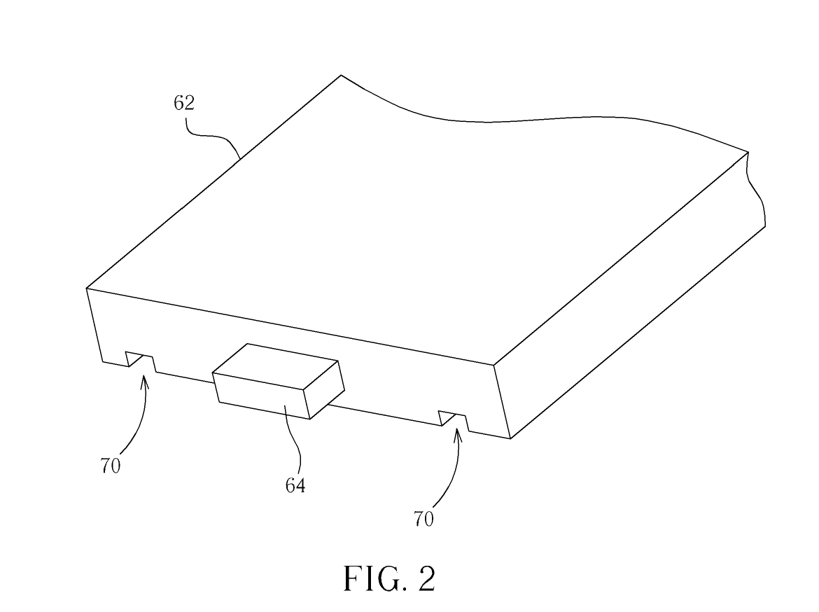

Please refer to FIG.1. FIG.1 is a diagram of a computer system 50 according to a preferred embodiment of the present invention. The computer system 50 includes a computer device 52 which can be a portable computer, such as a notebook computer. The computer deice 52 includes a housing 54 whereon an opening 56 is formed. A containing space 58 is formed inside the housing 54. The computer device 52 further includes a first magnetic module 60 exposing out of the opening 56 on the housing 54 partly and installed inside the housing 54 in a movable manner, such as in a rotatable manner or in a shiftable manner. The first magnetic module 60 can be a circular structure. The user can turn the part of the first magnetic module 56 exposing out of the opening 56 on the housing 54 so as to rotate the first magnetic module 60. The first magnetic module 60 includes a magnet 601 wedging in a plastic component 602. The first magnetic module 60 can include a plurality of pairs of poles. The computer system 50 further includes an external module 62 which can be contained in the containing space 58 inside the housing 54 of the computer device 52. The external module 62 can be an input module, such as a mouse, or can be a storage module, such as an optical disk drive and the like. Please refer to FIG.2. FIG.2 is an enlarged diagram of the external module 62 according to the preferred embodiment of the present invention.

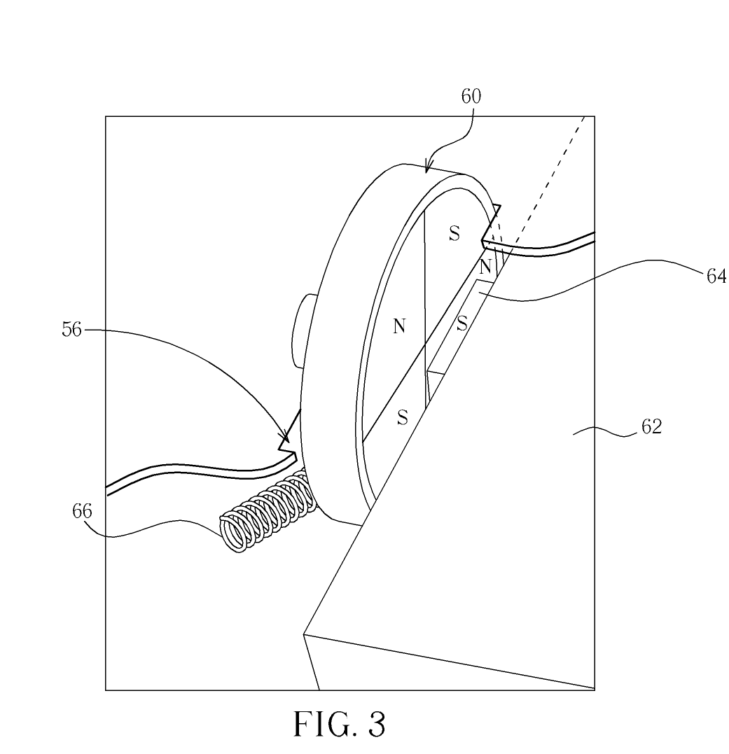

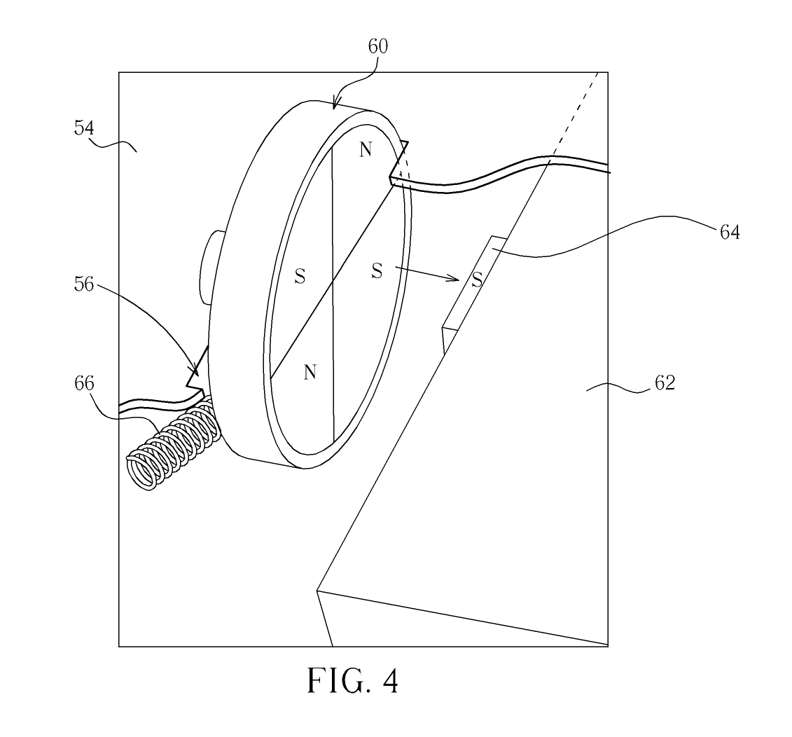

Please refer to FIG.3 and FIG.4. FIG.3 is a diagram of the first magnetic module 60 located in a first position according to the preferred embodiment of the present invention. FIG.4 is a diagram of the first magnetic module 60 located in a second position according to the preferred embodiment of the present invention. The user can turn the part of the first magnetic module 56 exposing out of the opening 56 on the housing 54 so as to switch the first magnetic module 60 in the first position or in the second position. Originally, the first magnetic module 60 is located in the first position, and a first pole of the first magnetic module 60 aims at a second pole of the second magnetic module 64 opposite to the first pole of the first magnetic module 60. The first pole of the first magnetic module 60 can be a magnetic north pole or a magnetic south pole, and the second pole of the second magnetic module 64 can be a magnetic south pole or a magnetic north pole accordingly. At this time, the first magnetic module 60 attracts the second magnetic module 64 for containing the external module 62 connected with the second magnetic module 64 inside the containing space 58 tightly.

When the user wants to use the external module 62, the user can turn the part of the first magnetic module 56 exposing out of the opening 56 on the housing 54 so as to switch the first magnetic module 60 from the first position to the second position. At this time, a second pole of the first magnetic module 60 aims at the second pole of the second magnetic module 64 same as the second pole of the first magnetic module 60. The second pole of the first magnetic module 60 can be a magnetic south pole or a magnetic north pole, and the second pole of the second magnetic module 64 can be a magnetic south pole or a magnetic north pole accordingly. At this time, the first magnetic module 60 repulses the second magnetic module 64 for ejecting the external module 62 connected with the second magnetic module 64 out of the containing space 58 so that the user can take the external module 62. When the first magnetic module 60 includes a plurality of pairs of poles alternately, the user can turn the first magnetic module 60 clockwise or counterclockwise for switching between different poles so that the first magnetic module 60 is capable of attracting or repulsing the second magnetic module 64.

In addition, the computer system 50 further includes a restoring component 66 connected to the first magnetic module 60 at one end and fixed on a fixing end at the other end. The restoring component 66 can be an elastic component, such as a spring. The elastic restoring force provided by the restoring component 66 can restore the first magnetic module 60 from the second position to the first position. That is, when the first magnetic module 60 is in the first position originally, the restoring component 66 is not deformed. When the first magnetic module 60 rotates from the first position to the second position, the restoring component 66 is deformed elastically as compression or extension with elastic energy. After the user release the part of the first magnetic module 60 exposing out of the opening 56, the elastic restoring force provided by the restoring component 66 drives the first magnetic module 60 to move in an opposite direction, that is, the elastic restoring force provided by the restoring component 66 drives the first magnetic module 60 form the second position to the first position. The first magnetic module 60 can attract the second magnetic module 64 for fixing the external module 62 inside the containing space 58 tightly when the user inserts the external module 62 into the containing space 58. The restoring component 66 can be disposed selectively, and the mechanism for switching the first magnetic module 60 between the first position and the second position is not limited to the above-mentioned embodiment. For example, a gear can be substituted for the restoring component 66. Furthermore, the first magnetic module 60 can be installed inside the housing 54 in a shiftable manner for switching between the first position and the second position. For example, the first magnetic module 60 can be pressed down for switching from the first position to the second position, and a restoring component is used for restoring the first magnetic module 60 from the second position to the first position. In conclusion, the mechanism for switching the attractive condition and the repulsive condition of the first magnetic module 60 and the second magnetic module 64 is within the scope of the present invention.

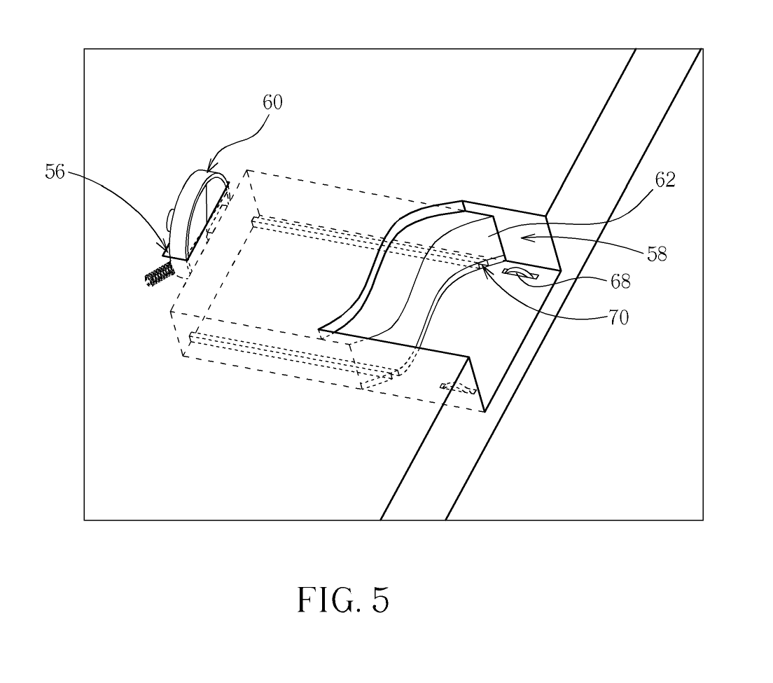

Please refer to FIG.5. FIG.5 is a diagram of the external module 62 contained inside the containing space 58 according to the preferred embodiment of the present invention. The computer system further includes a sliding component 68 disposed on a side of the containing space 58. The sliding component 68 can be a roller. At least one track 70 is formed on the external module 62 in a position located corresponding to the sliding component 68. The external module 62 is capable of sliding on the sliding component 68 via the track 70 so as to reduce resistant force when the external module 62 moves in the containing space 58.

In contrast to the prior art, the containing mechanism utilizes magnetic force to fix or eject the external module convenient. Furthermore, the containing space for containing the external module is hidden inside the housing of the computer device so as to keep aesthetic feeling of the computer device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A computer device comprising:
a housing having an opening formed on the housing and a containing space formed inside the housing;
a first magnetic module exposing out of the opening partly and installed inside the housing in a movable manner; and
a second magnetic module connected to an external module;
wherein when the first magnetic module moves to a first position, a first pole of the first magnetic module is located corresponding to a second pole of the second magnetic module so that the first magnetic module attracts the second magnetic module for containing the external module inside the containing space, and when the first magnetic module moves to a second position, a second pole of the first magnetic module is located corresponding to the second pole of the second magnetic module so that the first magnetic module repulses the second magnetic module for ejecting the external module out of the containing space.

2. The computer device of claim 1 wherein the first magnetic module comprises a plurality of pairs of poles.

3. The computer device of claim 1 wherein the first magnetic module is a circular structure.

4. The computer device of claim 1 wherein the first pole of the first magnetic module is a magnetic north pole, the second pole of the first magnetic module is a magnetic south pole, and the second pole of the second magnetic module is a magnetic south pole.

5. The computer device of claim 1 wherein the first pole of the first magnetic module is a magnetic south pole, the second pole of the first magnetic module is a magnetic north pole, and the second pole of the second magnetic module is a magnetic north pole.

6. The computer device of claim 1 further comprising a restoring component connected to the first magnetic module for restoring the first magnetic module from the second position to the first position.

7. The computer device of claim 6 wherein the restoring component is an elastic component.

8. The computer device of claim 7 wherein the elastic component is a spring.

9. The computer device of claim 1 further comprising a sliding component disposed on a side of the containing space wherein the external module is capable of sliding on the sliding component.

10. The computer device of claim 9 wherein the sliding component is a roller.

11. The computer device of claim 1 wherein the first magnetic module comprises a magnet.

12. The computer device of claim 11 wherein the first magnetic module further comprises a plastic component for covering the magnet.

13. The computer device of claim 1 wherein the first magnetic module is installed inside the housing in a rotatable manner for switching between the first position and the second position.

14. The computer device of claim 1 wherein the first magnetic module is installed inside the housing in a shiftable manner for switching between the first position and the second position.

15. A computer system comprising:
an external module; and
a computer device comprising:
a housing having an opening formed on the housing and a containing space formed inside the housing;
a first magnetic module exposing out of the opening partly and installed inside the housing in a movable manner; and
a second magnetic module connected to the external module;
wherein when the first magnetic module moves to a first position, a first pole of the first magnetic module is located corresponding to a second pole of the second magnetic module so that the first magnetic module attracts the second magnetic module for containing the external module inside the containing space, and when the first magnetic module moves to a second position, a second pole of the first magnetic module is located corresponding to the second pole of the second magnetic module so that the first magnetic module repulses the second magnetic module for ejecting the external module out of the containing space.

16. The computer system of claim 15 wherein the first magnetic module is a circular structure.

17. The computer system of claim 15 wherein the first pole of the first magnetic module is a magnetic north pole, the second pole of the first magnetic module is a magnetic south pole, and the second pole of the second magnetic module is a magnetic south pole.

18. The computer system of claim 15 wherein the first pole of the first magnetic module is a magnetic south pole, the second pole of the first magnetic module is a magnetic north pole, and the second pole of the second magnetic module is a magnetic north pole.

19. The computer system of claim 15 further comprising a restoring component connected to the first magnetic module for restoring the first magnetic module from the second position to the first position.

20. The computer system of claim 19 wherein the restoring component is an elastic component.

21. The computer system of claim 15 further comprising a sliding component disposed on a side of the containing space wherein the external module is capable of sliding on the sliding component.

22. The computer system of claim 21 wherein the sliding component is a roller.

23. The computer device system of claim 15 wherein the first magnetic module comprises a magnet.

24. The computer system of claim 23 wherein the first magnetic module further comprises a plastic component for covering the magnet.

25. The computer system of claim 15 wherein the first magnetic module is installed inside the housing in a rotatable manner for switching between the first position and the second position.

26. The computer system of claim 15 wherein the first magnetic module is installed inside the housing in a shiftable manner for switching between the first position and the second position.
